(19) United States
(12) Patent Application Publication
(10) Pub. No.: US 2009/0117714 A1
(43) Pub. Date: May 7, 2009

(54) Method of producing semiconductor device, and substrate processing apparatus

(75) Inventors: Naonori Akae, Toyama-shi (JP); Yushin Takasawa, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/153,043

(22) Filed: May 13, 2008

(30) Foreign Application Priority Data
May 14, 2007 (JP) 2007-127648

(51) Int. Cl. H01L 21/365

(52) U.S. Cl. 438/479; 118/666; 257/E21.463

(57) ABSTRACT

Disclosed is a method of producing a semiconductor device, comprising the steps of carrying a substrate with an insulating film formed on its surface into a processing chamber; processing the substrate to form silicon grains on the insulating film formed on the surface of the substrate by introducing at least a silicon-base gas into the processing chamber; and carrying the processed substrate out of the processing chamber, wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, in such a manner that the flow rate of the dopant gas could be equal to or more than the flow rate of the silicon-base gas.

### BACKGROUND OF THE INVENTION

1. Field of the Invention

The present invention relates to a method of producing a semiconductor device that includes the steps of forming nano-scale silicon fine island grains and forming a fine grain-size polysilicon, and to a substrate processing apparatus.

2. Background Art

With the reduction in operating power for fine processing and low consumption power flash memories, tunnel oxide films tend to be thinned. With the film thinning, however, device reliability depression owing to dielectric breakdown or stress-induced leak current is some concern, on the other hand. Accordingly, different from floating gate-type or insulating trap-type ones, silicon microcrystal memories having an intermediate memory structure have become specifically noted.

With the increase in the integration scale of DRAM, the gate electrode occupation area tends to decrease, and in that situation, it may be considered that the processing unevenness of polysilicon crystal grains in gate electrodes may result in the unevenness of electric properties. Accordingly, some investigations are made for reducing the grain size of polysilicon to thereby reduce the unevenness of individual gate electrodes.

To that effect, controlling the initial stage of silicon film formation on an insulating film according to such silicon microcrystal memory technique and polysilicon microprocessing technique is expected for development to various processes; however, since the important influence of the surface condition of the insulating film on the initial stage of silicon film formation thereon could not be grasped well, fine grain formation was difficult.

For fine grain formation, the condition for forming silicone microcrystals must be optimized; but the silicon grain density is significantly influenced by the surface condition of the underlying insulating film, and therefore it is important to suitably control the surface condition for fine grain formation thereon with good producibility.

In the above-mentioned silicon microcrystal memory technique and polysilicon microprocessing technique, the nuclear density in the grain formation process on a wafer surface must increase. However, in conventional nucleation, the nuclear density is generally controlled only by controlling the process condition, but the method has a problem in that a nuclear density on a nano-scale order is difficult to obtain; and it is desired to clarify the reason and to solve the problem.

### SUMMARY OF THE INVENTION

An object of the present invention is to solve the above-mentioned problems in the prior art and to provide a method of producing a semiconductor device and a substrate processing apparatus capable of greatly contributing to high nuclear density formation.

According to one embodiment of the invention, there is provided a method of producing a semiconductor device, comprising the steps of carrying a substrate with an insulating film formed on its surface into a processing chamber; processing the substrate to form silicon grains on the insulating film formed on the surface of the substrate by introducing at least a silicon-base gas into the processing chamber; and carrying the processed substrate out of the processing chamber, wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, in such a manner that the flow rate of the dopant gas could be equal to or more than the flow rate of the silicon-base gas.

According to another embodiment of the invention, there is provided a method of producing a semiconductor device, comprising the steps of: carrying a substrate with an insulating film formed on its surface into a processing chamber; processing the substrate to form silicon grains on the insulating film formed on the surface of the substrate by introducing at least a silicon-base gas into the processing chamber; and carrying the processed substrate out of the processing chamber, wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, and the thermal decomposition of the silicon-base gas is brought about as triggered by the action of the dopant gas.

According to still another embodiment of the invention, there is provided a substrate processing apparatus, comprising; a processing chamber that processes a substrate with an insulating film formed on its surface; a silicon-base gas supply system that feeds a silicon-base gas into the processing chamber; a dopant gas supply system that feeds a dopant gas into the processing chamber; an exhaust system that exhausts inside the processing chamber; a heater that heats the substrate in the processing chamber; and a controller that controls the silicon-base gas supply system, the dopant gas supply system, the exhaust system and the heater in such a manner that the temperature and the pressure inside the processing chamber could be set at a temperature and a pressure at which, when the silicon-base gas is introduced singly, the silicon-base gas is not thermally decomposed, wherein a silicon-base gas and a dopant gas are introduced into the processing chamber having the controlled temperature and pressure so that the flow rate of the dopant gas could be equal to or more than the flow rate of the silicon-base gas, thereby forming silicon grains on the insulating film formed on the surface of the substrate.

According to the invention, there are provided a method that produces a semiconductor device and a substrate processing apparatus capable of attaining well-controlled nucleation that forms high-density silicon grains and capable of securing stable performance.

### BRIEF DESCRIPTION OF THE DRAWINGS

FIG. 1 is a plan view of a substrate processing apparatus of an embodiment to which the invention is applied.

FIG. 2 is a cross-sectional view of the substrate processing apparatus of FIG. 1.

FIG. 3 is a schematic cross-sectional view of a processing furnace in a substrate processing apparatus of an embodiment of the invention.

FIG. 4 is a graphic view explaining a process of formation of silicon quantum dots and polysilicon.

FIG. 5 is a graph showing the relationship between the film formation time and the film thickness increase in Example 1 of the invention.

FIG. 6 shows a reaction image in Example 1 of the invention; and A is a graphic view of explaining a case with no pre-washing, and B is a graphic view of explaining a case with pre-washing.

FIG. 7 shows electromicroscopic pictures indicating the effect of silicon grain density control depending on the presence or absence of dopant gas supply and on the gas supply timing in Example 2 of the invention.

FIG. 8 shows the silicon-base gas and dopant gas supply timing in Example 2 of the invention.

FIG. 9 shows reaction form images of a case where a dopant gas is introduced before and/or during the processing for silicon grain formation (FIG. 9B); and a case where a dopant gas is not introduced (FIG. 9A).

FIG. 10 shows electromicroscopic pictures indicating the effect of silicon grain density control depending on the difference in the temperature inside the processing chamber and in the processing pressure in Example 3 of the invention.

FIG. 11 shows the silicon-base gas, dopant gas and inert gas supply timing and the processing pressure in Example 3 of the invention.

FIG. 12 shows reaction form images of a case where the processing of silicon grain formation is attained under low pressure (FIG. 12A); and a case where the processing is attained under high pressure (FIG. 12B).

FIG. 13 shows reaction form images of a case where the processing of silicon grain formation is attained at high temperature (FIG. 13A); and a case where the processing is attained at low temperature (FIG. 13B).

FIG. 14 shows reaction form images of a case where the processing of silicon grain formation is attained with a gas at a small flow rate (FIG. 14A); and a case where the processing is attained with a gas at a large flow rate (FIG. 14B).

FIG. 15 is a cross-sectional view showing a part of a flash memory that includes a floating gate constituted by silicon quantum dots.

FIG. 16 is a cross-sectional view showing a part of DRAM that includes a gate electrode constituted by a micrograin-size polysilicon film and a metal film.

In these drawings, 10 is a substrate processing apparatus, 112 is a wafer-carriage, 115 is an elevator, 202 is a processing furnace, 205 is a reactor tube, 207a is an upper heater, 207b is a lower heater, 208 is a heat-insulating material, 231 is an exhaust line, 232a is a gas introduction line, 232b is a gas introduction line, 244 is a gate valve, 247a is a temperature controller, 246 is a pressure controller, 249 is a main controller, 250 is a vacuum pump.

### DESCRIPTION OF THE PREFERRED EMBODIMENTS

Heretofore, for forming a silicon microcrystal memory that comprises silicon quantum dots or the like, generally employed is a process that comprises first introducing a silicon-base gas introduced into a processing chamber having a substrate kept therein, thereby forming island silicon grains, or that is, silicon quantum dots on the substrate under a non-dope condition, thereafter carrying the substrate out of the processing chamber, and then doping the formed silicon quantum dots according to an ion implantation method or the like. However, the present inventor has found that, when the silicon quantum dot formation is attained in the presence of a dopant gas given thereto, then silicon quantum dots may be formed while doping the impurities. Further, the inventor has found that, when a silicon-base gas and a dopant gas of which the flow rate is equal to or more than that of the silicon-base gas are introduced into a processing chamber in which the temperature and the pressure are so controlled that, in case where the silicon-base gas is introduced thereinto singly, the silicon-base gas is not thermally decomposed under the controlled condition, then the silicon-base gas may be thermally decomposed, as triggered by the action of the dopant gas, whereby the nuclear density of the silicon grains may be increased, and that this is a heretofore unknown and unexpected effect.

The present invention is based on the inventor's findings mentioned above, and for example, in a process that forms fine silicon grains that forms a silicon microcrystal memory or a gate electrode that comprises silicon quantum dots or the like, on the surface of a predetermined insulating film of a semiconductor chip, a silicon-base gas and a dopant gas are introduced into the processing chamber in which the temperature and the pressure are so controlled that, in case where the silicon-base gas is introduced thereinto singly, the silicon-base gas is not thermally decomposed under the controlled condition, in such a manner that the flow rate of the dopant gas could be equal to more than the flow rate of the silicon-base gas, whereby the Si nuclear density is increased.

Embodiments of the invention are described below with reference to the drawings.

### Embodiments to Which the Invention is Applied

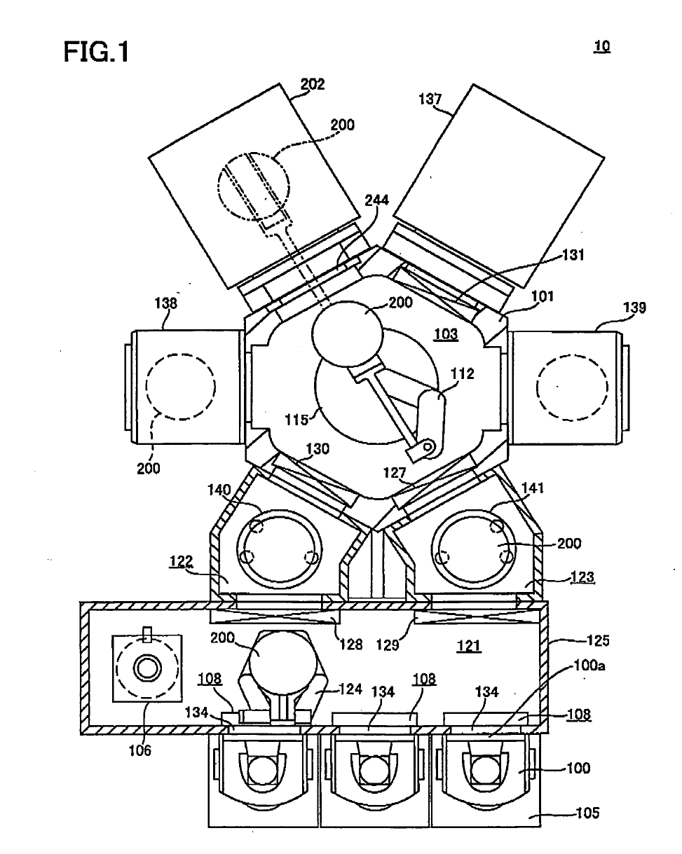

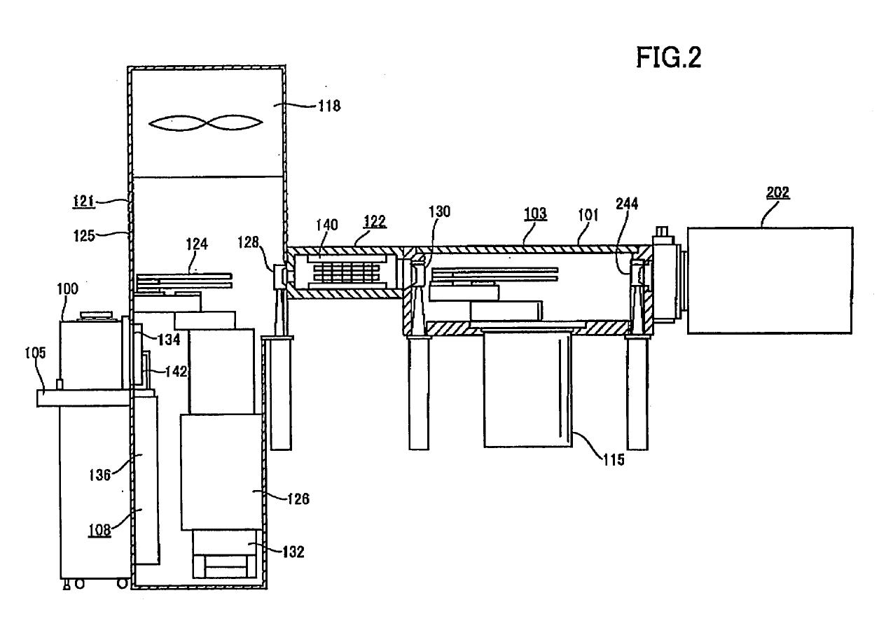

First, with reference to FIG. 1 and FIG. 2, the outline of the substrate processing apparatus 10 to which the invention is applied is described. In the substrate processing apparatus 10 to which the invention is applied, FOUP (front opening unified pod—hereinafter this is referred to as “pod”) is used as the carrier that carries the substrate such as wafer. In the following description, the front and the back, and the right and the left are all based on FIG. 1. Specifically, relative to the space in which FIG. 1 is drawn, the front means below the space; the back means above the space; and the right and the left are the right and the left of the space.

As in FIG. 1 and FIG. 2, the substrate processing apparatus 10 is provided with a first transfer chamber 103 designed to have a road lock chamber structure that is resistant to pressure lower than atmospheric pressure (negative pressure) such as a vacuum state; and the housing 101 of the first transfer chamber 103 is formed to have a box shape of such that its plan view is hexagonal and both its upper and lower sides are closed. In the first transfer chamber 103, disposed is a first wafer carriage 112 capable of carrying two wafers 200 at the same time under negative pressure. The first wafer carriage 112 is so designed that it may move up and down by the elevator 115 while keeping the airtightness in the first transfer chamber 103.

Of six side walls of the housing 101, the front-positioned two side walls are connected to a carry-in preliminary chamber 122 and a carry-out preliminary chamber 123 via gate valves 130 and 127, respectively; and the two chambers are both so designed as to have a road lock chamber structure resistant to negative pressure. Further, in the preliminary chamber 122, disposed is a carry-in substrate stand 140; and in the preliminary chamber 123, disposed is a carry-out substrate stand 141.

On the front side of the preliminary chamber 122 and the preliminary chamber 123, a second transfer chamber 121 to be used under nearly atmospheric pressure is connected thereto via gate valves 128 and 129. In the second transfer chamber 121, disposed is a second wafer carriage 124 that carries the wafer 200. The second wafer carriage 124 is so designed that it may move up and down by the elevator 126 disposed in the second transfer chamber 121, and may move back and forth in the right and the left directions by the linear actuator 132.

As in FIG. 1, a notch finder or an orientation flat aligner 106 is disposed in the left side area of the second transfer chamber 121. As in FIG. 2, a clean unit 119 that supplies clean air is disposed in the upper area of the second transfer chamber 121.

As in FIG. 1 and FIG. 2, a wafer carry-in and carry-out port 134 that carries the wafer 200 in and out of the second transfer chamber 121 through it, and a pod opener 108 are disposed on the front side of the housing 125 of the second transfer chamber 121. An IO stage 105 is disposed on the opposite side to the pod opener 108 via the wafer carry-in and carry-out port 134 therebetween, or that is, outside the housing 125. The pod opener 108 is provided with a closer 142 capable of opening and shutting the cap 100a of the pod 100 and capable of closing the wafer carry-in and carry-out port 134, and a driving unit 136 that drives the closer 142; and opening and shutting the cap 100a of the pod 100 mounted on the IO stage 105 makes it possible to carry the wafer 200 in and out of the pod 100. The pod 100 is so designed that it may be led in and out of the IO stage 105, by a rail guided vehicle (RGV) (not shown).

As in FIG. 1, of six side walls of the housing 101, the rear-positioned two side walls (on the backside) are connected to a first processing furnace 202 and a second processing furnace 137 that processes a wafer in a desired manner, via gate valves 244 and 131 adjacent thereto, respectively. The first processing furnace 202 and the second processing furnace 137 are both hot-wall type processing furnaces. Of six side walls of the housing 101, the remaining two side walls facing each other are connected to a first cleaning unit 139 and a second cleaning unit 139, respectively; and the first cleaning unit 138 and the second cleaning unit 139 are both so designed as to cool the processed wafer 200 therein.

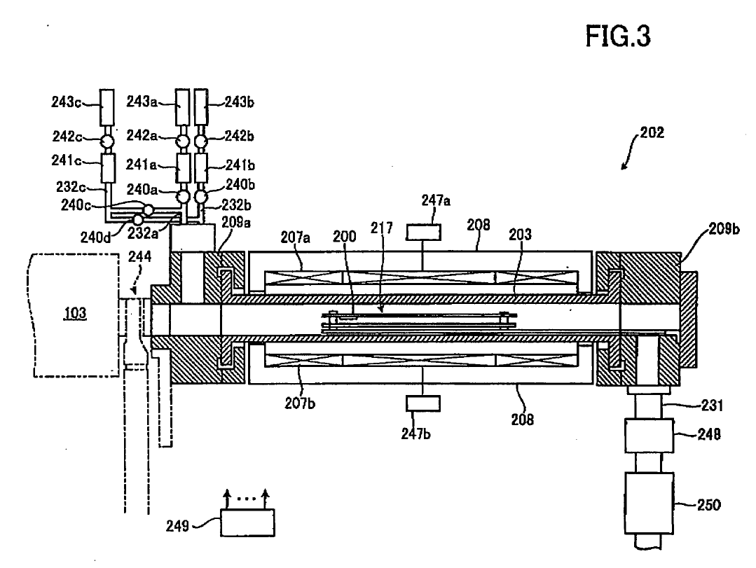

Next, with reference to FIG. 3, the outline of the first processing furnace 202 of the substrate processing apparatus 10 of the embodiment of the invention is described. FIG. 3 is a schematic vertical cross-sectional view of the first processing furnace 202 of the substrate processing apparatus 10 of the embodiment of the invention.

The reactor tube 203 as a reaction container made of quartz, silicon carbide or alumina has a flat space in the horizontal direction, and forms a processing chamber inside it to house a wafer 200 as a substrate therein. A wafer support stand 217 as a supporting tool that supports the wafer 200 is provided inside the reactor tube 203; on both sides of the reactor tube 203, provided are a gas introduction flange 209a and a gas exhaust flange 209b as airtight manifolds; and the first transfer chamber 103 is connected to the gas introduction flange 209a via a gate valve 244 as a partitioning valve.

A first gas introduction line 232a and a second gas introduction line 232b as supply ducts are connected to the gas introduction flange 209a. A first gas source 243a and a second gas source 243b are connected to the first gas introduction line 232a and the second gas introduction line 232b, respectively. On the way of the first gas introduction line 232a and the second gas introduction line 232b, provided are a first mass flow controller 241a and a second mass flow controller 241b as flow rate controlling units (flow rate controlling means) that controls the flow rate of the first gas and the second gas to be introduced into the reactor tube 203 from the first gas source 243a and the second gas source 243b, and first valves 242a and 240b and second valves 242b and 240b disposed on the upstream side and the downstream side thereof, respectively.

A third gas introduction line 232c is connected to the first gas introduction line 232a and the second gas introduction line 232b. A third gas source 243c is connected to the third gas introduction line 232c; and on the way of the third gas introduction line 232c, provided are a third mass flow controller 241c that controls the flow rate of the third gas to be introduced into the reactor tube 203 from the third gas source, and a third valve 242c disposed on the upstream side thereof. The third gas introduction line 232c is branched into two lines on the downstream side from the third mass flow controller 241c; and the branches are separately connected to the first gas introduction line 232a on the downstream side thereof from the first valve 240a, and to the second gas introduction line 232b on the downstream side thereof from the second valve 240b, thereby making it possible to supply the third gas to the respective lines. In the branches of the third gas introduction lines 232c, separately disposed are a fourth valve 240c and a fifth valve 240d. In this embodiment, an inert gas as a third gas, for example, N₂, Ar or He is put in the third gas source 243c.

An exhaust line 231 as an exhaust pipe is connected to the gas exhaust flange 209b. In addition, a vacuum pump 250 as a degassing unit (degassing means) that degasses the reactor tube 203 is connected to the exhaust line 231; and on the way thereto, provided is a pressure controller 248 as a pressure controlling unit (pressure controlling means) that controls the pressure inside the reactor tube 203.

An upper heater 207a and a lower heater 207b as heating units (heating means) are disposed in the top and the bottom of the reactor tube 203 so as to heat the inside of the reactor tube 203 uniformly or with a predetermined temperature profile. Temperature controllers 247a and 247b as temperature controlling units (temperature controlling means) that controls the heater temperature are connected to the upper heater 207a and the lower heater 207b. A heat-insulating material 208 as a heat-insulating member is provided so as to cover the upper heater 207a, the lower heater 207b and the reactor tube 203.

The temperature inside the reactor tube 203, the pressure inside the reactor tube 203 and the flow rate of the gas to be fed to the reactor tube 203 are controlled by the temperature controllers 247a and 247b, the pressure controller 248, and the mass flow controllers 241a, 241b and 241c, so as to be a predetermined temperature, pressure and flow rate. The temperature controllers 247a and 247b, the pressure controller 248, and the mass flow controllers 241a, 241b and 241c are controlled by a main controller 249 as a main controlling unit (main controlling means). The main controller 249 is so designed that it also controls the opening and shutting of the valves 242a, 240a, 242b, 240b, 242c, 240c and 240d to there by controlling the timing of gas supply. Further, the main controller 249 is so designed as to control the operation of the constitutive members of the substrate processing apparatus 10.

Next described is a method for processing a wafer as a substrate, as one process in production of a semiconductor device, using the first processing furnace 202 of the substrate processing apparatus 10 mentioned above. In the following description, the operation of the constitutive members of the substrate processing apparatus 10 is controlled by the main controller 249.

An insulating film of a thin silicon oxide film or the like is formed on the wafer 200 as a substrate having a semiconductor chip thereon, in a step-prior to the present process. The electric properties of the processed substrate are influenced by the thickness of the insulating film, and therefore it is extremely important to control and manage the thickness of the thin film. Accordingly, heretofore, after a thin film as an insulating film has been formed, the substrate is not washed prior to the present process, or that is, prior to the process of forming silicon grains.

As opposed to this, in this embodiment, the semiconductor chip-having wafer is previously washed with, for example, a diluted aqueous hydrofluoric acid solution (DHF) that removes the surface-contaminants such as spontaneous oxide films or organic contaminants, before it is led into the present substrate processing apparatus, and thereafter dried with a spin drier, and immediately carried into the preliminary chamber inside the substrate processing apparatus while it is still kept clean. The substrate is processed immediately while it is kept clean, and this is for the purpose of preventing the bad influences to be caused by the contamination of the atmosphere in a clean room, and the substrate must be suitably managed and controlled so as to be prevented from being contaminated before it is carried in the substrate processing apparatus. In this stage, when many contaminants adhere to or form on the wafer surface, then silicon grains having a desired size and a desired density could not be formed since the density of chemical bonds of silicon differs between on the surface of the insulating film and on the surface thereof covered with organic contaminants, and as a result, the yield of semiconductor devices may lower.

According to this embodiment, the surface of the insulating film formed on the surface of a substrate is washed and cleaned, and then the substrate is immediately put into the substrate processing apparatus, in which the substrate is processed while it is kept clean; and therefore, not depending on the surface condition of the substrate that varies depending on the condition in which the substrate is stored, silicon grains may be stably formed on the substrate.

As mentioned in the above, the unprocessed wafer 200 of which the surface has been washed is kept in the pod 100, in which 25 such wafers are kept. In that condition, the wafers are carried into the substrate processing apparatus in which they are processed, by the rail guided vehicle in the apparatus. As in FIG. 1 and FIG. 2, the thus-carried pod 100 is put on the IO stage 105, as transferred from the rail guided vehicle. The cap 100a of the pod 100 is removed by the pod opener 108, and the wafer take-in and take-out port of the pod 100 is thus opened.

When the pod 100 is opened by the pod opener 108, the second wafer carriage 124 disposed in the second transfer chamber 121 picks up the wafer 200 from the pod 100, and carries it into the preliminary chamber 122; and the wafer 200 is thus put on the substrate stand 140. During the transfer operation, the gate valve 130 on the first transfer chamber 103 of the preliminary chamber 122 is kept shut, and the negative pressure inside the first transfer chamber 103 is kept as such. After a predetermined number of, for example, 25 wafers 200 kept in the pod 100 have been transferred onto the substrate stand 140, the gate valve 128 is shut and the preliminary chamber 122 is degassed to have a negative pressure by means of a degassing unit (not shown).

After the pressure inside the preliminary chamber 122 has reached a predetermined level, the gate valve 130 is opened, whereby the preliminary chamber 122 and the first transfer chamber 103 are made to communicate with each other. Next, the first wafer carriage 112 of the first transfer chamber 103 picks up two wafers 200 from the substrate stand 140 and carries them into the first transfer chamber 103. After the gate valve 130 is shut, the first transfer chamber 103 and the first processing furnace 202 are made to communicate with each other. Specifically, in a condition in which the temperature inside the reactor tube 203 is kept at the processing temperature by the heaters 207a and 207b, the gate valve 244 is opened, and the wafers 200 are carried into the reactor tube 203 by the first wafer carriage 112, and then put on the wafer support stand 217. In this embodiment, two wafers 200 are put on the wafer support stand 217, and the two wafers 200 are processed at the same time. In order that the two wafers 200 to be processed at the same time could have the same heat history, the two wafers 200 are carried into the reactor tube 203 at the same time. At the same time when the wafers 200 are carried into the reactor tube 203, the reactor tube 203 is preheated up to the processing temperature of the wafers 200. On the wafer support stand 217, only one wafer 200 may be put so that one wafer 200 could be processed in one operation. In such a case, it is desirable that a dummy wafer is put on the support area not supporting the wafer 200 of the wafer support stand 217.

After the first wafer carriage 112 goes back and the gate valve 244 is shut, the pressure inside the reactor tube 203 is controlled by the pressure controller 248 to be the processing pressure (pressure stabilization), and the temperature inside the reactor tube 203 is controlled by the temperature controller 247a to be the processing temperature (temperature stabilization). During the pressure stabilization inside the reactor tube 203 and the temperature stabilization of the wafers 200, an inert gas is introduced into the reactor tube 203 from the third gas source 243c via the third gas introduction line 232c and via at least any of the first gas introduction line 232a and the second gas introduction line 232b, whereby the reactor tube 203 may have an inert gas atmosphere inside it.

After the pressure inside the reactor tube 203 has been stabilized to be the processing pressure and the temperature of the wafers 200 has been stabilized to be the processing temperature, a processing gas is introduced into the reactor tube 203 whereby the wafers 200 are processed. Specifically, silicon grains are formed on the insulating film formed on the wafers 200.

In this stage, a silicon-base gas such as SiH₄ or Si₂H₆ is introduced into the reactor tube 203 to form silicon grains; however, the silicon grain density is heretofore on a level of from 10¹⁰ grains/cm² to 10¹¹ grains/cm². When the length of the gate electrode becomes shorter with the increase in the scale of device integration, formation of fine silicon grains at high density is desired for the purpose of reducing the unevenness thereof. However, according to the conventional method, it is difficult to form silicon grains at a desired density level of 10¹² grains/cm².

Therefore, in the process of the present invention, a dopant gas such as PH₃, B₂H₆, BCl₃ or AsH₃ is used and the substrate is processed under the condition under which a large number of nucleation sites for silicon grains are formed, whereby the density of the silicon grains formed is increased.

Specifically, in this embodiment, a silicon-base gas such as SiH₄ or Si₂H₆, as a first gas is put in the first gas source 243a and a dopant gas such as PH₃, B₂H₆, BCl₃ or AsH₃ as a second gas is in the second gas source 243b; and after the processing pressure inside the reactor tube 203 has been stabilized to the processing pressure and the temperature of the wafers 200 have been stabilized, the silicon-base gas as the first gas and the dopant gas as the second gas are introduced into the reactor tube 203 from the first gas source 243a and the second gas source 243b via the first gas introduction line 232a and the second gas introduction line 232b, according to the timing mentioned below, whereby silicon grains are formed on the insulating film formed on the wafer 200.

Concretely, into the reactor tube 203, (1) a dopant gas is first introduced, and after the dopant gas introduction has been stopped, a silicon-base gas is then introduced thereinto to form silicon grains; or (2) a dopant gas and a silicon-base gas are introduced at the same time to form silicon grains; or (3) a dopant gas is first introduced, and while the dopant gas introduction is kept as such, a silicon-base gas is introduced to form silicon grains.

During the processing to form silicon grains, the temperature and the pressure inside the processing chamber are so controlled that, when the silicon-base gas is introduced singly to the chamber, the silicon-base gas is not thermally decomposed under the controlled condition, and the flow rate of the dopant gas is made equal to or more than the flow rate of the silicon-base gas.

Specifically, (1) prior to the processing to form silicon grains, or (2) during the processing to form silicon grains, or (3) prior to or during the processing to form silicon grains, a dopant gas is introduced into the processing chamber and, in addition, the temperature and the pressure inside the processing chamber are so controlled that, when the silicon-base gas is introduced singly to the chamber, the silicon-base gas is not thermally decomposed under the controlled condition, and the flow rate of the dopant gas is made equal to or more than the flow rate of the silicon-base gas. According to the process, it is possible to form silicon grains on a level of 10¹² grains/cm², as described hereinunder.

The processing condition for processing wafers in the processing furnace in this embodiment, or that is, for forming silicon grains on the insulating film formed on the surface of a wafer therein is, for example, as follows: The processing temperature is from 200 to 400° C., the processing pressure is from 130 to 1330 Pa, the silicon-base gas (SiH₄) flow rate is from 100 to 2000 sccm, the dopant gas (B₂H₆) flow rate is from 100 to 2000 sccm. The individual processing condition is kept at a predetermined level within the defined range, whereby silicon grains may be formed with increasing the number of nucleation sites for the silicon grains.

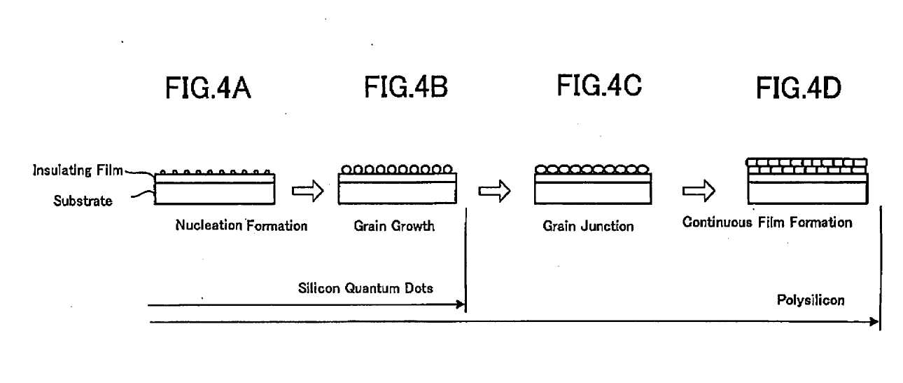

Next, with reference to FIG. 4, the process from nucleation to continuous film formation is described. As in FIG. 4A, when a silicon-base gas is supplied, then nuclei are formed on the insulating film on the surface of a substrate, and thereafter as in FIG. 4B, crystals grow around those nuclei serving as the center thereof. The grown crystals are referred to as grains. As in FIG. 4C, when the grains further grow, they are kept in contact with each other; and as in FIG. 4D, when the distance between the adjacent grains is lost, a continuous film, polysilicon film is formed. When the grain growth is stopped in the condition in which the grains are independent of each other before they are brought into contact with each other, then island grains, or that is, silicon quantum dots are formed.

In the present invention, prior to and/or during the processing to form grains, or that is, prior to the silicon-base gas supply and/or during the silicon-base gas supply, a dopant gas is introduced into the chamber and the processing to form grains is attained under the above-mentioned processing temperature, processing pressure and gas flow rate condition for increasing the nucleation sites to thereby increase the nuclear density. Accordingly, in forming silicon quantum dots, the density of silicon grains may be increased; and in forming a polysilicon film, the grain size of the grains constituting the polysilicon film may be reduced.

When the processing of the wafers 200 is finished, the remaining gas is removed from the reactor tube 203, for which an inert gas as a third gas is introduced into the reactor tube 203 from the third gas source 243c via the third gas introduction line 232c and via at lease any of the gas introduction lines 232a and 232b, and is discharged through the exhaust line 231, and the reactor tube 203 is thereby purged.

After the purging of the reactor tube 203, the pressure inside the reactor tube 203 is controlled by the pressure controller 248 to be the water transfer pressure. After the pressure inside the reactor tube 203 has reached the transfer pressure, the processed wafers 200 are carried out by the first wafer carriage 112 from the reactor tube 203 into the first transfer chamber 103. Specifically, after the processing of the wafers 200 has been finished in the first processing furnace 202 and after the purging has been finished, the gate valve 1224 is opened and the processed two wafers 200 are carried out into the first transfer chamber 103 by the first wafer carriage 112. After the wafer transfer, the gate valve 244 is shut.

The first wafer carriage 112 carries the two wafers 200 that have been carried out from the first processing furnace 202 into the first cleaning unit 138, and the two processed wafers 200 are then cooled.

When the processed wafers 200 are carried into the first cleaning unit 138, then the first wafer carriage 112 picks up two wafers 200 previously prepared on the substrate stand 140 in the preliminary chamber 122 at the same time like the same operation as that mentioned in the above, and carries them into the first processing furnace 202, and the two wafers 200 are processed in a desired manner simultaneously in the first processing furnace 202.

After a predetermined period of time in the first cleaning unit 138, the cooled two wafers 200 are carried out from the first cleaning unit 138 into the first transfer chamber 103 by the first wafer carriage 112.

After the cooled two wafers 200 have been carried out from the first cleaning unit 138 into the first transfer chamber 103, the gate valve 127 is opened. The first wafer carriage 112 carries the two wafers 200 that has been carried out from the first cleaning unit 138, into the preliminary chamber 123, then puts them on the substrate stand 141, and thereafter the preliminary chamber 123 is shut by the gate valve 127.

The above operation is repeated, whereby a predetermined number of, for example, 25 wafers 200 carried in the preliminary chamber 122 are then processed subsequently two by two.

After the processing of all the wafers 200 carried in the preliminary chamber 122 has been finished, then all the processed wafers 200 have been put in the preliminary chamber 123 and thereafter the preliminary chamber 123 has been shut by the gate valve 127, then the preliminary chamber 123 is restored to nearly the atmospheric pressure by an inert gas introduced thereinto. After the preliminary chamber 123 has been restored to nearly the atmospheric pressure, the gate valve 129 is opened, and the cap 100a of the empty pod 100 set on the IO stage 105 is opened by the pod opener 108. Next, the second wafer carriage 124 in the second transfer chamber 121 picks up the wafers 200 from the substrate stand 141, and carries them into the second transfer chamber 121, and the wafers 200 are then put into the pod 100 through the wafer carry-on and carry-out port 134 of the second transfer chamber 121. After the 25 processed wafers 200 have been completely put into the pod 100, the cap 100a of the pod 100 is shut by the pod opener 108. The thus-shut pod 100 is transferred from the IO stage 105 to the next step by the rail guided vehicle in the apparatus.

The above operation is described with reference to a case of using the first processing furnace 202 and the first cleaning unit 138; and the same operation may be carried out also in a case of using the second processing furnace 137 and the second cleaning unit 139. In the above-mentioned substrate processing apparatus 10, the preliminary chamber 122 is a carry-in chamber and the preliminary chamber 123 is a carry-out chamber; but contrary to this, the preliminary chamber 123 may be a carry-in chamber and the preliminary chamber 122 may be a carry-out chamber.

In the first processing furnace 202 and the second processing furnace 137, the same treatment may be carried out or different treatments may be carried out. In case where different treatments are carried out in the first processing furnace 202 and the second processing furnace 137, for example, in the first processing furnace 202, a wafer 200 may be processed for a certain purpose, for example, for washing the insulating film formed on the surface of the substrate, and then in the second processing furnace 137, it may be processed for a different purpose, for example, for forming silicon grains as in the embodiment illustrated herein. In case where a wafer 200 is processed for a certain purpose in the first processing furnace 202 and then it is processed for a different purpose in the second processing furnace 137, the wafer 200 may be led to run through the first cleaning unit 138 or the second cleaning unit 139.

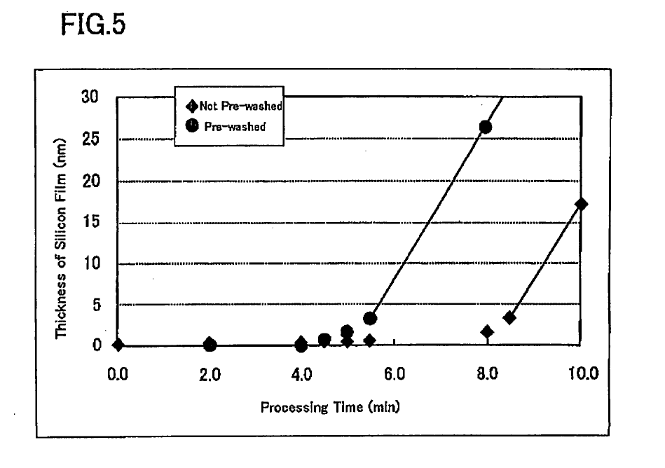

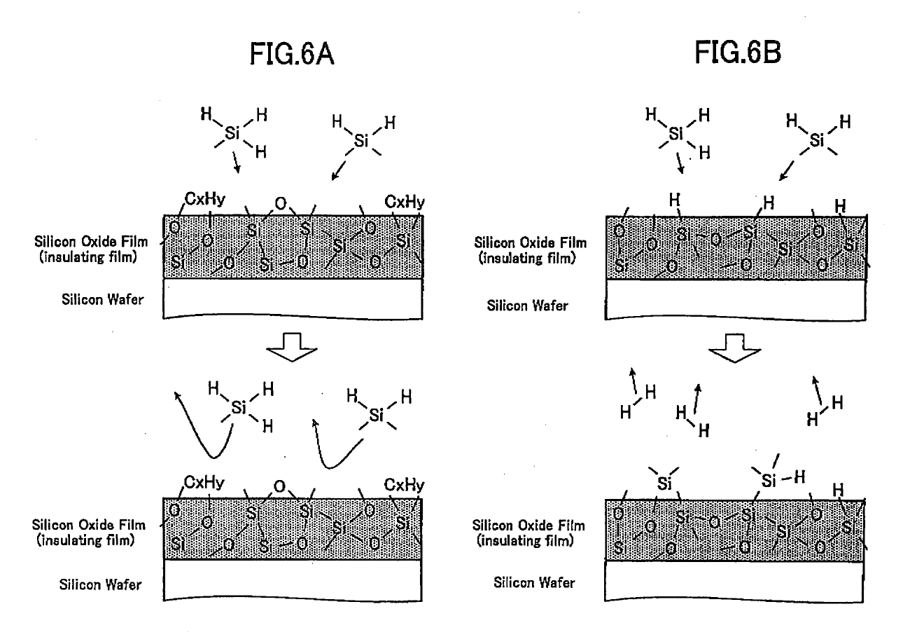

Next described is Example 1 with reference to FIG. 5 and FIG. 6.

### Example 1

FIG. 5 shows how the thickness of the silicon film formed on the surface of a wafer increases with the lapse of the processing time when a wafer is processed, using the above-mentioned substrate processing apparatus 10, in two different methods; or that is, in one method where the wafer surface (the surface of the insulating film) is washed prior to the water processing, and in the other method where the wafer surface is not washed prior to the wafer processing. In the graph, the horizontal axis indicates the processing time (min), or that is, it indicates the silicon-base gas supply time; and the vertical axis indicates the thickness (nm) of the silicon film formed on the insulating film on the wafer surface. “Not pre-washed” means that the wafer surface is not washed prior to the wafer processing; and “pre-washed” means that the wafer surface is washed prior to the wafer processing. In both cases, the processing condition for wafer processing was the same. Concretely, the wafer processing was as follows: The processing temperature was kept at a predetermined level within a range of from 200 to 800° C., the processing pressure was within a range of from 13 to 1330 Pa, and the silicon-base gas (SiH₄) flow rate was within a range of from 10 to 2000 sccm. In Example 1, only a silicon-base gas was used for the processing, and a dopant gas was not used. The silicon-base gas was monosilane (SiH₄).

In ordinary direct processing with no washing treatment, the result is that the time taken before the increase in the thickness of the silicon film is at least 8 minutes, as in the graph of FIG. 5 with “not pre-washed”. During this period of 8 minutes, the wafer surface has a repetitive reaction cycle of silicon-base gas decomposition, surface adsorption, migration and dissociation; and it is presumed that the density of the chemical bonds for silicon-base gas adsorption on the wafer surface may decrease owing to the contaminants thereon since the wafer surface is not pre-washed, and including the reduction in the adsorption possibility, the film formation start time would be a minutes later. The reduction in the adsorption possibility means that there exist a factor of reducing the density of silicon grains on the wafer surface, and in general, it is presumed that silicon grains grow in the three-dimensional direction from those having a low grain density and the film may thereby increase. Under the surface condition, it is shown that the formation of silicon grains could not be controlled by the silicon-base gas supply condition.

As opposed to this, the case with pre-washing is as follows. As in FIG. 5 with “pre-washed”, the time taken before the increase in the silicon film thickness is about 5 minutes; and as compared with the case with “not pre-washed”, the time is shortened by about 3 minutes. The difference of 3 minutes may depend on the number of the chemical bonds existing in the wafer surface. As so mentioned in the above, the wafer surface has a repetitive reaction cycle of silicon-base gas decomposition, surface adsorption, migration and dissociation; and in case where the wafer surface is pre-washed, the chemical bond density of the wafer surface for silicon base-gas adsorption may differ from that of the water surface not pre-washed, or that is, the chemical bond density of the pre-washed wafer surface may be larger than that of the non-washed one, and therefore, the chemical bond density may be determined by the wafer surface condition. As a result, the adsorption possibility may increase when the wafer surface is pre-washed.

With reference to FIG. 6, the reaction form in the case with pre-washing and that in the case with no pre-washing are described. FIG. 6 shows a reaction image in the case with pre-washing and that in the case with no pre-washing. Depending on the cleaned condition of the surface of the insulating film formed on a silicon substrate, the reaction form varies. Specifically, in the case with no pre-washing prior to the processing step for silicon grain formation, different contaminant molecules (CxHy, O, etc.) bond to the chemical bonds of the insulating film when the silicon-base gas reacts on the film surface, as in FIG. 6A, and in this case, silicon grains are hardly formed. In other words, the formation of silicon grains depends on the surface condition, and therefore, the silicon grain formation could not be controlled by the silicon-base gas supply condition. As opposed to this, in the case with pre-washing, the surface of the insulating film is in a cleaned surface condition with no contaminants adhering thereto, and when atoms capable of readily leaving at low temperature such as hydrogen (H) bond to the chemical bonds of the insulating film, as in FIG. 6B, then silicon grains may be readily formed on the film surface. In other words, the silicon grain formation can be controlled by the silicon-base gas supply condition.

Accordingly, in the invention, as described in the above embodiment, the semiconductor surface is cleaned by pretreatment (pre-washing) before processed for silicon grain formation thereon in a processing chamber (reaction container), whereby nuclei for forming fine silicon grains may be formed in a well-controlled manner. As a result, semiconductor devices with stable performance may be secured.

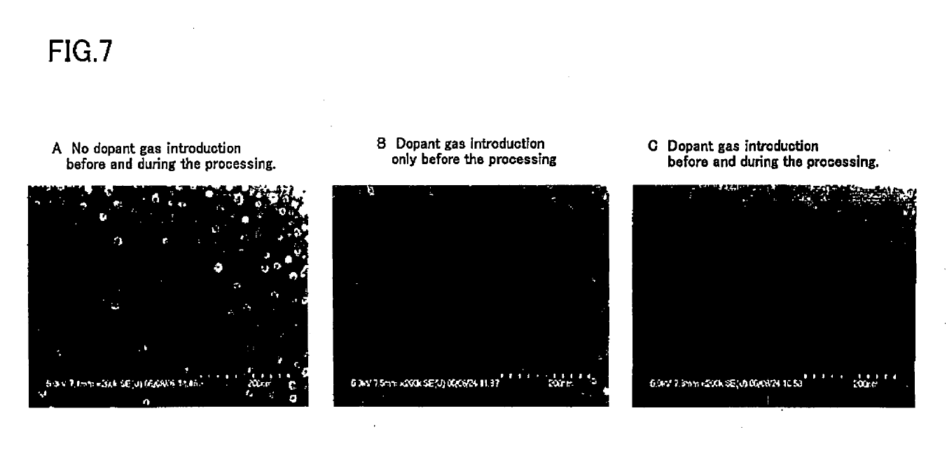

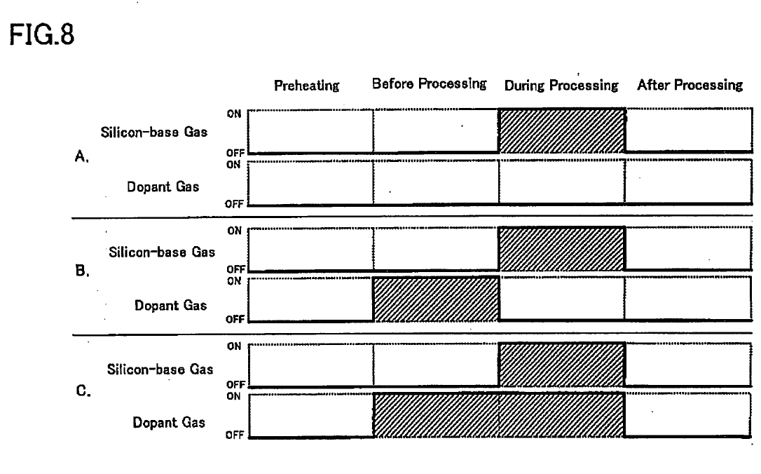

Next described is Example 2 with reference to FIG. 7 and FIG. 8.

### Example 2

FIG. 7 shows electromicroscopic pictures indicating the effect of silicon grain density control depending on the presence or absence of dopant gas supply and on the gas supply timing, found through experiments made by the use of the processing furnace of the substrate processing apparatus 10 described in the above. FIG. 8 shows the silicon-base gas and dopant gas supply timing. In this Example, monosilane (SiH₄) was used as the silicon-base gas; and diborane (B₂H₆) was used as the dopant gas. The wafer processing was as follows: The processing temperature was kept at a predetermined level within a range of from 200 to 800° C., the processing pressure was within a range of from 13 to 1330 Pa, the silicon-base gas (SiH₄) flow rate was within a range of from 10 to 2000 sccm, and the dopant gas (B₂H₆) flow rate was within a range of from 10 to 2000 sccm. In this Example, the wafer was pre-washed in the same manner as in the above embodiment, and then processed.

The three pictures A, B and C are of wafers processed according to different sequences A, B and C, respectively, as in FIG. 8. Specifically, the sequence A is a case where a dopant gas is not introduced before and during the processing to form silicon grains, but a silicon-base gas alone is introduced; the sequence B is a case where a dopant gas is introduced only before the processing; and the sequence C is a case where a dopant gas is continuously introduced before and during the processing. In this experiment, the reaction system was so controlled as to change the timing of dopant gas introduction.

In the conventional case where no dopant gas is introduced, the silicon grain density is on a level of 10¹¹ grains/cm², as in FIG. 7A; but as in FIG. 7B and FIG. 7C, the silicon grain density increased in the case where a dopant gas was introduced.

This Example confirms that, in the case where a dopant gas is introduced before and during the processing to form silicon grains, the density of the silicon grains formed is on a high level of 10¹² grains/cm², as in FIG. 7C, and that the silicon grain density in this case is about 10 times higher than that in the case where no dopant gas is introduced before and during the processing to form silicon grains as in FIG. 7A.

This means that the dopant gas introduction changes the wafer surface condition to be different from the wafer surface condition in the case with no dopant gas introduction, in point of the chemical bond density and the chemical bond condition in the wafer surface for silicon-base gas adsorption.

It may be considered that the density difference by 10 times may depend on the condition of the chemical bonds in the wafer surface. As so mentioned hereinabove, in case where silicon grains are formed with introduction of a silicon-base gas into the processing system, the wafer surface has a repetitive reaction cycle of silicon-base gas surface adsorption, migration, decomposition and dissociation; and the dopant atoms and the hydrogen atoms released from the dopant gas are adsorbed by the wafer surface, whereby the density of the chemical bonds for silicon-base gas adsorption may increase as compared with a case with no dopant gas introduction, or the silicon-base gas decomposition possibility may increase owing to the hydrogen adsorption to facilitate the silicon-base gas decomposition, therefore resulting in the increase in the silicon grain density.

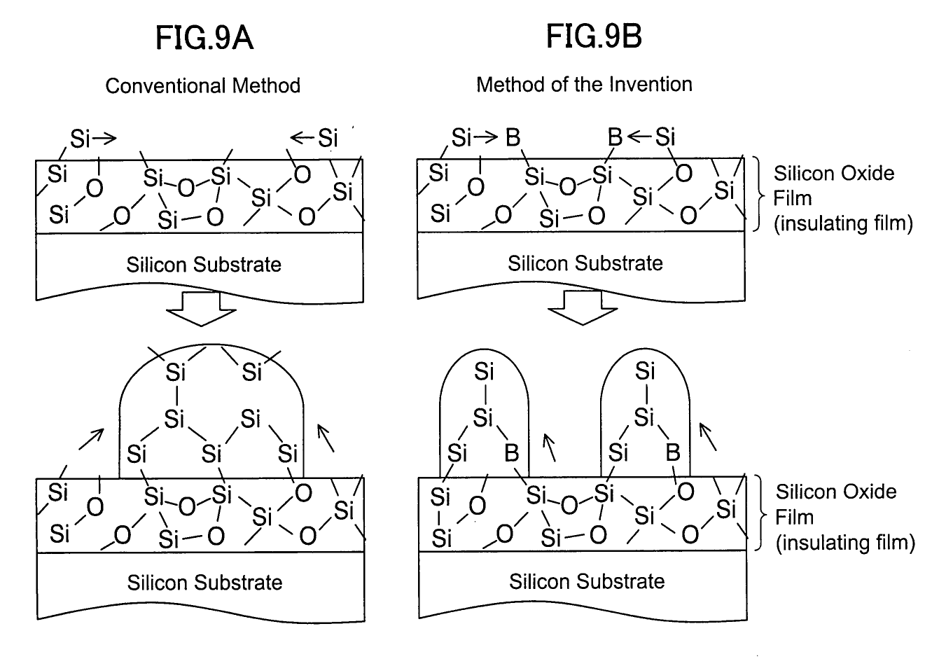

With reference to FIG. 9, the reaction form in the case with dopant gas introduction before and/or during the processing to form silicon grains, and the reaction form in the case with no dopant gas introduction are described. FIG. 9 shows reaction form images of a case where a dopant gas is introduced before and/or during the processing for silicon grain formation (FIG. 9B); and a case where a dopant gas is not introduced (FIG. 9A).

In the case where a dopant gas is introduced into the system before or during, or before and during the processing for silicon grain formation on the surface of an insulating film formed on a silicon substrate, the dopant gas bonds to the chemical bonds in the surface of the insulating film, on the surface of the insulating film. In FIG. 9B, the boron (B)-containing dopant gas is decomposed, and the released dopant atom, or that is, the boron atom bonds to the chemical bond in the surface of the insulating film. Accordingly, the formation of silicon grains on the surface of the insulating film depends on the adsorbed condition of the dopant gas and the dopant atom on the surface of the insulating film.

Silicon grains are formed as follows: A silicon-base gas is adsorbed by the surface of an insulating film, then the silicon (Si) atoms released through decomposition of the gas migrate on the surface of the insulating film and fix in the site where plural silicon atoms have gathered, thereby forming silicon grains. Accordingly, in the case where a dopant gas is adsorbed by the surface of an insulating film, the dopant gas restricts the migration range of the silicon atoms as in the lower view of FIG. 9E, and as a result, fine silicon grains may be formed at high density. In other words, the silicon grain formation may be controlled by dopant gas supply and by the condition of dopant gas supply.

As opposed to this, in the case where no dopant gas is introduced into the system before and/or during the processing for silicon grain formation, the range of silicon atom movement is not restricted, as in FIG. 9A; and therefore, as compared with the case with dopant gas introduction, it is more difficult to form fine silicon grains at high density in this case.

In that manner, in the invention, for the purpose of forming silicon grains at high density, a dopant gas is introduced into the processing chamber before or during, or before and during the processing of forming silicon grains by introducing a silicon-base base thereinto; and therefore, nuclei for forming high-density silicon grains may be formed in a well-controlled manner, and accordingly, the invention has realized the security of stable performance of the semiconductor devices produced.

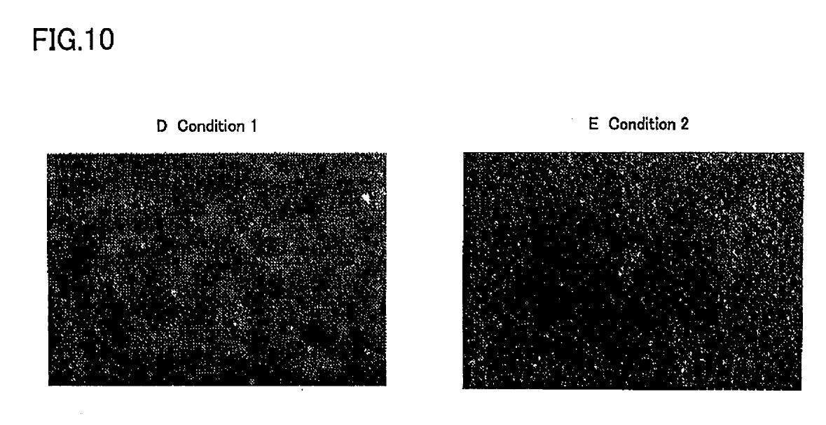

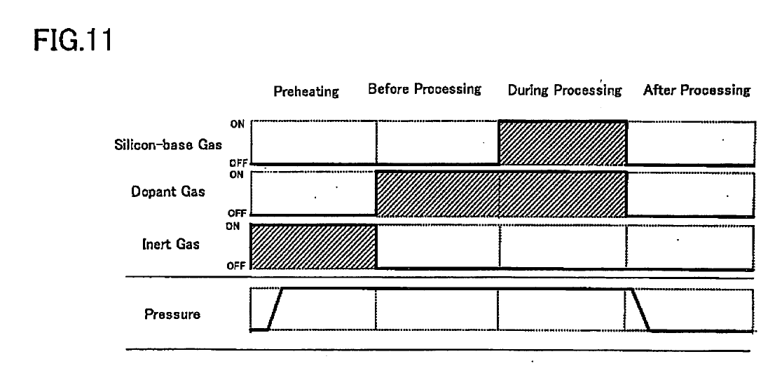

Next described is Example 3 with reference to FIGS. 10 and 11.

### Example 3

FIG. 10 shows electromicroscopic pictures indicating the effect of silicon grain density control depending on the difference in the processing temperature, the processing pressure and the gas flow rate, found through experiments made by the use of the processing furnace of the substrate processing apparatus 10 mentioned in the above. FIG. 11 shows the silicon-base gas and dopant gas supply timing. In this Example, monosilane (SiH₄) was used as the silicon-base gas; and diborane (B₂H₆) was used as the dopant gas. In this Example, the wafer was pre-washed in the same manner as in the above-mentioned embodiment, and then processed.

Two pictures D and E are the results of wafer processing made according to the sequence of FIG. 11. For these, however, the processing conditions differ. The picture D is the case of the processing condition 1 mentioned below; and the picture E is the case of the processing condition 2 mentioned below.

The processing condition 1 is as follows: The temperature and the pressure in the processing chamber are so controlled that, when a silicon-base gas alone is introduced into the chamber, then the silicon-base gas is thermally decomposed at the controlled temperature and pressure; and for the purpose of suppressing the silicon grain growth, the processing pressure is set low, and the overall flow rate, or that is the sum of the flow rate of the dopant gas and the flow rate of the silicon-base gas is set relatively low. Concretely, the processing condition 1 is as follows: The processing temperature was kept at a predetermined level within a range of from 500 to 700° C., the processing pressure was within a range of from 10 to 100 Pa, the silicon-base gas (SiH₄) flow rate was within a range of from 10 to 100 sccm, and the dopant gas (B₂H₆) flow rate was within a range of from 10 to 50 sccm. Under the controlled condition, the wafer was processed.

On the other hand, the processing condition 2 is as follows: The temperature and the pressure in the processing chamber are so controlled that, when a silicon-base gas alone is introduced into the chamber, then the silicon-base gas is not thermally decomposed at the controlled temperature and pressure; and for the purpose of securing the speed for silicon grain growth, the processing pressure is set high; and for the purpose of promoting the silicon-base gas decomposition, the flow rate of the dopant gas is made equal to or more than the flow rate of the silicon-base gas, and the overall gas flow rate is controlled under the condition. Concretely, the processing condition 2 is as follows: The processing temperature was kept at a predetermined level within a range of from 200 to 400° C., the processing pressure was within a range of from 130 to 1330 Pa, the silicon-base gas (SiH₄) flow rate was within a range of from 100 to 2000 sccm, and the dopant gas (B₂H₆) flow rate was within a range of from 100 to 2000 sccm. Under the controlled condition, the wafer was processed. The experiments were carried out while the processing temperature, the processing pressure and the gas flow rate were controlled in the manner as above.

As a result of the experiments, in the case of the processing under the condition 1, in which the temperature and the pressure were so controlled that, when the silicon-base gas alone is introduced into the chamber, then the silicon-base gas is thermally decomposed, and in which the temperature was relatively high, the pressure was relatively low and the flow rate was relatively small, the density of the silicon grains formed was 7×10¹¹ grains/cm². In the case of the processing under the condition 2, in which the temperature and the pressure were so controlled that, when the silicon-base gas alone is introduced into the chamber, then the silicon-base gas is not thermally decomposed, and in which the temperature was relatively low, the pressure was relatively high and the flow rate was relatively large, the density of the silicon grains formed was 1.3×10¹² grains/cm². In that manner, in the condition 2, the silicon grain density increased by about 2 times as compared with that in the condition.

The reason why the silicon grain density in the condition 2 is higher than that in the condition 1 may be because of the difference in the reaction cycle of silicon-base gas surface adsorption, migration, decomposition and dissociation on the wafer surface resulting from the difference in the processing condition. Specifically, silicon grain formation under high pressure as in this Example increases the surface adsorption possibility. On the other hand, silicon grain formation at low temperature inhibits migration, hardly inducing silicon grain bonding together. Further, when the dopant gas flowrate is made equal to or more than the silicon-base gas flow rate and when the overall gas flow rate is increased, then the silicon-base gas decomposition is accelerated, and in that condition, silicon grains may be formed even at a temperature at which the silicon-base gas alone is not thermally decomposed. From these reasons, it is considered that the silicon grain density would have increased under the condition 2, as compared with that under the condition 1.

In addition to the above-mentioned silicon grain density increase mentioned above, another advantage of large gas flow rate is that the gas flow rate increase may unify the silicon density distribution and the silicon particle size distribution in the wafer surface. The silicon grain size may be controlled by controlling the silicon-base gas flow time.

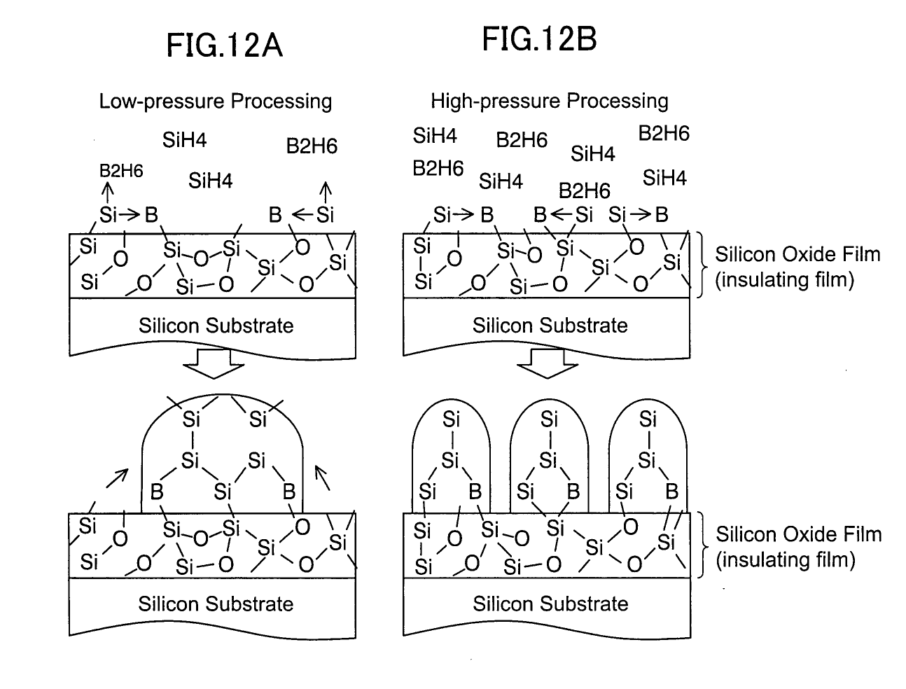

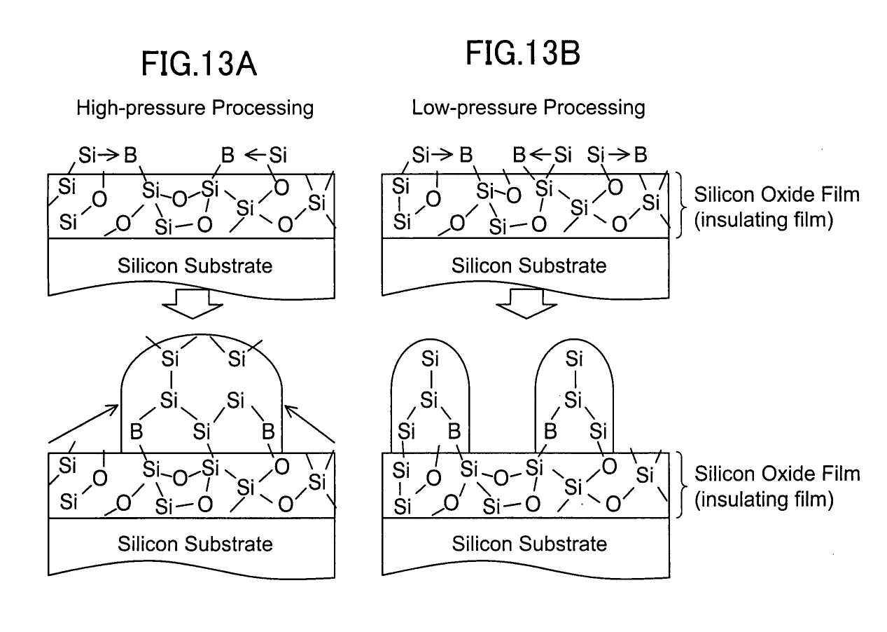

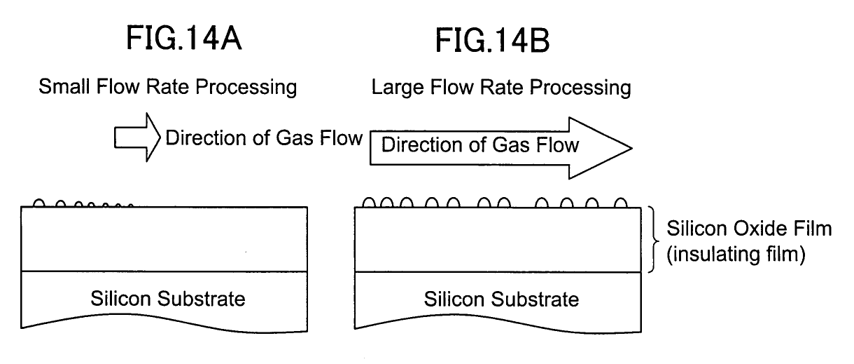

With reference to FIG. 12, described are reaction forms of a case where the processing of silicon grain formation is attained under low pressure and a case where the processing is attained under high pressure; with reference to FIG. 13, described are reaction forms of a case where the processing of silicon grain formation is attained at high temperature and a case where the processing is attained at low temperature; and with reference to FIG. 14, described are reaction forms of a case where the processing of silicon grain formation is attained with a gas at a small flow rate and a case where the processing is attained with a gas at a large flow rate. In the following description, one example of the silicon-base gas is SiH₄, and one example of the dopant gas is B₂H₆.

FIG. 12 shows reaction form images of a case where the processing of silicon grain formation is attained under low pressure (FIG. 12A); and a case where the processing is attained under high-pressure (FIG. 12B). As in FIG. 12, when the surface of an insulating film formed on a silicon substrate is processed for forming silicon grains thereon, the surface of the insulating film has a repetitive reaction cycle of silicon-base gas surface adsorption, dissociation, decomposition into silicon atom (Si), and silicon atom surface migration. In the case where the processing of silicon grain formation is attained under high pressure (FIG. 12B), as compared with the case where the processing is attained under low pressure (FIG. 12A), large quantities of the silicon-base gas and the dopant gas, or that is, many SiH₄ molecules and B₂H₆ molecules may exist in the reaction space, and therefore the surface adsorption of the silicon-base gas and the dopant gas increases. Much silicon-base gas adsorbed by the surface is decomposed into silicon atoms (Si), and much dopant gas is into dopant atoms, or that is, into boron atoms (B), and they bond to the chemical bonds in the surface of the insulating film.

Silicon grains are formed in a process where the silicon-base gas is adsorbed by the surface of the insulating film, then the silicon atoms (Si) formed through decomposition of the gas migrate on the surface of the insulating film and fix in the site where plural silicon atoms have gathered, thereby forming silicon grains. Accordingly, in the case where a large number of dopant atoms are adsorbed by the surface of the insulating film, the dopant atoms restrict the migration range of the silicon atoms, as in the lower view of FIG. 12B, and as a result, fine silicon grains can be formed at high density. Specifically, the dopant gas supply or the condition for the dopant gas supply may control the formation of silicon grains.

Under high pressure, large quantities of the silicon-base gas and the dopant gas, or that is, many SiH₄ molecules and B₂H₆ molecules exists in the reaction space, and the migration of the silicon atoms adsorbed by the surface of the insulating film is restricted by the silicon-base gas and the dopant gas, as blocked by them. As a result, under high processing pressure, fine silicon grains may be formed at higher density. Specifically, the silicon grain formation may be controlled by the pressure condition in the processing to form silicon grains.

FIG. 13 shows reaction form images of a case where the processing of silicon grain formation is attained at high temperature (FIG. 13A); and a case where the processing is attained at low temperature (FIG. 13B). As in FIG. 13, when the surface of an insulating film formed on a silicon substrate is processed for forming silicon grains thereon, the surface of the insulating film has a repetitive reaction cycle of silicon-base gas surface adsorption, dissociation, decomposition into silicon atom (Si), and silicon atom surface migration. In the case where the processing of silicon grain formation is attained at low temperature (FIG. 13B), as compared with the case where the processing is attained at high temperature (FIG. 13A), the energy of the silicon atoms adsorbed by the surface of the insulating film is lower, and therefore the surface migration of the silicon atoms is restricted and the atoms hardly bond to each other. As a result, fine silicon grains may be formed at high density. Specifically, the silicon grain formation may be controlled by the pressure condition in the processing to form silicon grains.

When the processing to form silicon grains is attained at high temperature as in the lower view of FIG. 13A, the energy of the silicon atoms adsorbed by the surface of the insulating film is high, and the silicon atoms migrate on the surface, and therefore, the silicon atoms may readily bond to each other with the result that the density of the formed silicon grains is difficult to increase. In addition, when the processing to form silicon grains is attained at high temperature, the growing speed of silicon grains is high and therefore it is difficult to control the grain size.

FIG. 14 shows reaction form images of a case where the processing of silicon grain formation is attained with a gas at a small flow rate (FIG. 14A); and a case where the processing is attained with a gas at a large flow rate (FIG. 14B). In the processing to form silicon grains, when the dopant gas flow rate is made equal to or more than the silicon-base gas flow rate and when the overall gas flow rate is large (FIG. 14B), the silicon gas flow speed and the dopant gas flow speed on the surface of the insulating film formed on the silicon substrate is high, as compared with a case where the overall gas flow is small (FIG. 14A), and therefore, the silicon grains formed hardly have grain size distribution, or that is, the silicon grain distribution may be readily unified (FIG. 14B). On the other hand, when the processing is attained at a small overall gas flow rate, the silicon grain distribution may be uneven since the gas flow speed is slow (FIG. 14A). In addition, since the dopant gas flow rate is increased, the catalytic effect of the dopant gas is remarkable and the silicon-base gas decomposition is thereby promoted, and therefore silicon grains may be formed even at a temperature at which the silicon-base gas alone does not decompose by itself. Specifically, the dopant gas plays a role of triggering silicon-base gas decomposition. In addition, since the gas flow rate is large, large quantities of the silicon-base gas and the dopant gas, or that is, many SiH₄ molecules and B₂H₆ molecules exist in the processing space, and in this case, the same reaction as in the high-pressure processing case of FIG. 12 may also occur.

In the manner as above, when the processing for silicon grain formation is attained under high pressure and low temperature under which the silicon-base gas alone is not thermally decomposed, and when the dopant gas flow rate is made equal to or more than the silicon-base gas flow rate and the flow rate is kept large, then silicon grains may be formed at high density; and in addition, the silicon grain size may be readily controlled by controlling the time for which the silicon-base gas and the dopant gas are applied to the substrate.

As described in the above, in the case where formation of high-density silicon grains is desired as in this Example, the temperature and the pressure in the processing chamber are set at a temperature and a pressure at which the silicon-base gas alone introduced into the chamber is not thermally decomposed, and for the purpose of securing the growing speed of silicon grains, the pressure in the processing chamber is set high, and for promoting the silicon-base gas decomposition, the dopant gas flow rate is made equal to or more than the silicon-base gas flow rate; and as a result, nuclei for forming high-density silicon grains can be formed favorably. Accordingly, as in this Example, the invention provides a method that produces semiconductor devices, securing the stable performance of the semiconductor devices produced.

The technique that the dopant gas flow rate is equal to the silicon-base gas flow rate may include a case where the dopant gas flow rate is 390 sccm and the silicon-base gas flow rate is 400 sccm, or that is the dopant gas flow rate is only slightly smaller than the silicon-base gas flow rate. In case where B₂H₆ is used as the dopant gas and SiH₄ is used as the silicon-base gas and where the SiH₄ flow rate is 400 sccm and the B₂H₆ flow rate is 390 sccm, this may exhibit the same effect as that of the case where both the SiH₄ flow rate and the B₂H₆ flow rate are 400 sccm each, as confirmed through experiments.

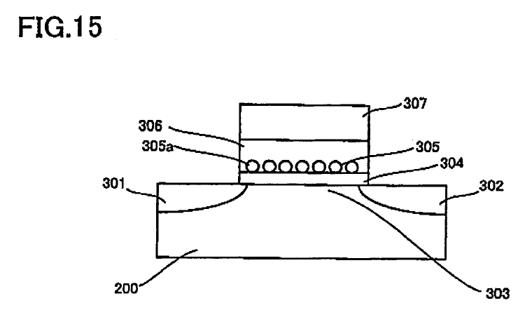

Next described is an example of a method that produces a semiconductor device. This is an example of applying the substrate processing apparatus and method of the invention to flash memory production, or in other word, this is an example of applying the substrate processing apparatus and method of the invention to a process of forming a floating gate of a flash memory with silicon quantum dots. FIG. 15 is a cross-sectional view showing a part of a flash memory that includes a floating gate constituted by silicon quantum dots.

First, a tunnel oxide film 304 of an insulating material such as a silicon oxide film (SiO₂ film) is formed on the surface of a wafer 200. The tunnel oxide film 304 is, for example, formed according to a thermal oxidation method of dry oxidation or wet oxidation.

Next, according to the substrate processing apparatus and method of the invention, formed is a floating gate electrode 305 that comprises plural island grains, or that is, silicon quantum dots 305a. The silicon quantum dots 305a are formed, for example, as semi-spheres or spheres.

Next formed is an insulating layer 306 of an insulating material having a laminate structure of, for example, silicon oxide film (SiO₂ film)/silicon nitride film (Si₃N₄ film)/silicon oxide film (SiO₂ film) to cover the floating gate electrode 305. The SiO₂ film to constitute the insulating layer 306 may be formed, for example, according to a CVD method of using SiH₂Cl₂ gas and N₂O gas; and the Si₃N₄ film may be formed, for example, according to a CVD method of using SiH₂Cl₂ gas and NH₃ gas. Next, on the insulating layer 306, formed is a control gate electrode 307 comprising, for example, a phosphorus (P)-added polysilicon film (poly-Si film). The control gate electrode 307 is formed, for example, according to a CVD method of suing SiH₄ gas and PH₃ gas. Accordingly, the control gate electrode 307 is formed above the floating gate electrode 305.

Finally, a source 301 and a drain 302 of impurity regions with an n-type impurity added thereto are formed on the major surface of the wafer 200, according to an ion implantation method. Between the source 301 and the drain 302, formed is a channel region 303. According to the above process, a flash memory of FIG. 15 is produced.

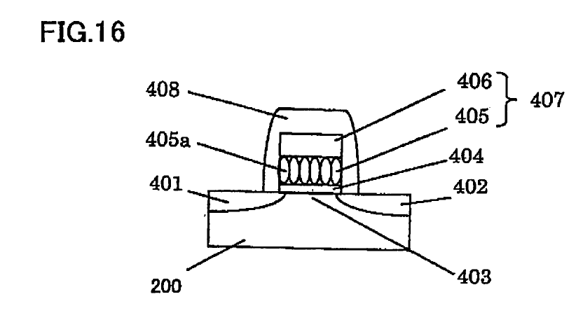

Next described is another example of a method that produces a semiconductor device. This is an example of applying the substrate processing apparatus and method of the invention to DRAM production, or in other word, this is an example of applying the substrate processing apparatus and method of the invention to a process of forming a micrograin-size polysilicon film for a part of the gate electrode of DRAM. FIG. 16 is a cross-sectional view showing a part of DRAM that includes a gate electrode constituted by a micrograin-size polysilicon film and a metal film.

First, a gate oxide film 404 comprising an insulating material such as a silicon oxide film (SiO₂) or a silicon oxinitride film (SiON) is formed on the surface of a silicon wafer 200. The gate oxide film 404 is formed, for example, according to a thermal oxidation method of dry oxidation or wet oxidation.

Next, according to the substrate processing apparatus and method of the invention, a polysilicon film 405 comprising fine grains 405a is formed on the gate oxide film 404. Next, a metal film 406 of tungsten (W) or the like is formed on the polysilicon film 405. The metal film 406 may be formed, for example, according to an ALD method or a CVD method. Accordingly, a gate electrode 407 is formed, comprising the micrograin-size polysilicon film 405 and the metal film 406. Next, an insulating film 408 of, for example, a silicon nitride film (Si₃N₄ film) is formed to cover the gate electrode 407. The Si₃N₄ film to constitute the insulating layer 408 may be formed, for example, according to a CVD method of using SiH₂Cl₂ gas and NH₃ gas.

Finally, a source 401 and a drain 402 of impurity regions with an n-type impurity added thereto are formed on the major surface of the wafer 200, according to an ion implantation method. Between the source 401 and the drain 402, formed is a channel region 403. According to the above process, a DRAM gate structure of FIG. 16 is produced.

### INDUSTRIAL APPLICABILITY

The invention is applicable to a method that produces a semiconductor device and a substrate processing apparatus, for example, for flash memory and DRAM.

As claimed in the claims stated below, the invention includes the following embodiments:

According to one embodiment of the invention, there is provided a method of producing a semiconductor device, comprising the steps of: carrying a substrate with an insulating film formed on its surface into a processing chamber; processing the substrate to form silicon grains on the insulating film formed on the surface of the substrate by introducing at least a silicon-base gas into the processing chamber; and carrying the processed substrate out of the processing chamber, wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, in such a manner that the flow rate of the dopant gas could be equal to or more than the flow rate of the silicon-base gas.

Preferably, in the processing step, the silicon-base gas is thermally decomposed as triggered by the action of the dopant gas.

Preferably, in the processing step, the temperature inside the processing chamber is from 200 to 400° C., the pressure inside the processing chamber is from 130 to 1330 Pa, the flow rate of the silicon-base gas is from 100 to 2000 sccm, and the flow rate of the dopant gas is from 100 to 2000 sccm.

Preferably, the method further comprises the step of washing the surface of the insulating film formed on the surface of the substrate, prior to the step of carrying the substrate into the processing chamber.

Preferably, the method further comprises the step of washing the surface of the insulating film formed on the surface of the substrate, with an aqueous diluted hydrofluoric acid solution, prior to the step of carrying the substrate into the processing chamber.

Preferably, in the processing step, the dopant gas is introduced before the silicon-base gas introduction and/or during the silicon-base gas introduction.

Preferably, in the processing step, the growth of said silicon grains is stopped before said silicon grains are contacted with one another to thereby form island silicon grains.

Preferably, in the processing step, said silicon grains are made to grow so that said silicon grains could be contacted with one another to thereby form continuous silicon grains.

Preferably, in the processing step, SiH₄ or Si₂H₆ is introduced as the silicon-base gas, and PH₃, B₂H₆, BCl₃ or AsH₃ is introduced as the dopant gas.

According to another embodiment of the invention, there is provided a method of producing a semiconductor device, comprising the steps of: carrying a substrate with an insulating film formed on its surface into a processing chamber; processing the substrate to form silicon grains on the insulating film formed on the surface of the substrate by introducing at least a silicon-base gas into the processing chamber; and carrying the processed substrate out of the processing chamber, wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, and the thermal decomposition of the silicon-base gas is brought about as triggered by the action of the dopant gas.

According to still another embodiment of the invention, there is provided a substrate processing apparatus, comprising: a processing chamber that processes a substrate with an insulating film formed on its surface; a silicon-base gas supply system that feeds a silicon-base gas into the processing chamber; a dopant gas supply system that feeds a dopant gas into the processing chamber; an exhaust system that exhausts inside the processing chamber; a heater that heats the substrate in the processing chamber; and a controller that controls the silicon-base gas supply system, the dopant gas supply system, the exhaust system and the heater in such a manner that the temperature and the pressure inside the processing chamber could be set at a temperature and a pressure at which, when the silicon-base gas is introduced singly, the silicon-base gas is not thermally decomposed, wherein a silicon-base gas and a dopant gas are introduced into the processing chamber having the controlled temperature and pressure so that the flow rate of the dopant gas could be equal to or more than the flow rate of the silicon-base gas, thereby forming silicon grains on the insulating film formed on the surface of the substrate.

Preferably, the controller controls the dopant gas supply system in order that the silicon-base gas begins to be thermally decomposed as triggered by the action of the dopant gas.

Preferably, the controller controls the heater, the exhaust system, the silicon-base gas supply system and the dopant gas supply system in order that the temperature inside the processing chamber could be from 200 to 400° C., the pressure inside the processing chamber could be from 130 to 1330 Pa, the silicon-base gas flow rate could be from 100 to 2000 sccm and the dopant gas flow rate could be from 100 to 2000 sccm.

Preferably, the controller controls the silicon gas supply system and the dopant gas supply system in order that the dopant gas could be fed into the processing chamber before and/or during the silicon-base gas introduction thereinto.

Preferably, the controller controls the silicon-base gas supply system and the dopant gas supply system in order that the growth of the formed silicon grains may be stopped before said silicon grains are contacted with one another.

Preferably, the controller controls the silicon-base gas supply system and the dopant gas supply system in order that the formed silicon grains may continue to grow until said grains are contacted with one another.

Preferably, the silicon-base gas supply system supplies SiH₄ or Si₂H₆, and the dopant gas supply system supplies PH₃, B₂H₆, BCl₃ or AsH₃.

According to still another embodiment of the invention, there is provided a substrate processing apparatus comprising a processing chamber that processes a substrate with an insulating film formed on its surface, a silicon-base gas supply system that feeds a silicon-base gas into the processing chamber, a dopant gas supply system that feeds a dopant gas into the processing chamber, an exhaust system that exhausts inside the processing chamber, a heater that heats the substrate in the processing chamber, and a controller that controls the apparatus in such a manner that the temperature and the pressure inside the processing chamber could be set at a temperature and a pressure at which, when the silicon-base gas is introduced singly, the silicon-base gas is not thermally decomposed, wherein a silicon-base gas and a dopant gas are introduced into the processing chamber having the controlled temperature and pressure, and the thermal decomposition of the silicon-base gas is brought about as triggered by the action of the dopant gas, to form silicon grains on the insulating film formed on the surface of the substrate.

What is claimed is:

1. A method of producing a semiconductor device, comprising the steps of
carrying a substrate with an insulating film formed on its surface into a processing chamber;
processing the substrate to form silicon grains on the insulating film formed on the surface of the substrate by introducing at least a silicon-base gas into the processing chamber; and
carrying the processed substrate out of the processing chamber,
wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, in such a manner that the flow rate of the dopant gas could be equal to or more than the flow rate of the silicon-base gas.

2. The method of producing the semiconductor device according to claim 1, wherein in the processing step, the silicon-base gas is thermally decomposed as triggered by the action of the dopant gas.

3. The method of producing the semiconductor device according to claim 1, wherein in the processing step, the temperature inside the processing chamber is from 200 to 400° C., the pressure inside the processing chamber is from 130 to 1330 Pa, the flow rate of the silicon-base gas is from 100 to 2000 sccm, and the flow rate of the dopant gas is from 100 to 2000 sccm.

4. The method of producing the semiconductor device according to claim 1, which further comprises the step of washing the surface of the insulating film formed on the surface of the substrate, prior to the step of carrying the substrate into the processing chamber.

5. The method of producing the semiconductor device according to claim 1, which further comprises the step of washing the surface of the insulating film formed on the surface of the substrate, with an aqueous diluted hydrofluoric acid solution, prior to the step of carrying the substrate into the processing chamber.

6. The method of producing the semiconductor device according to claim 1, wherein in the processing step, the dopant gas is introduced before the silicon-base gas introduction and/or during the silicon-base gas introduction.

7. The method of producing the semiconductor device according to claim 1, wherein in the processing step, the growth of said silicon grains is stopped before said silicon grains are contacted with one another to thereby form island silicon grains.

8. The method of producing the semiconductor device according to claim 1, wherein in the processing step, said silicon grains are made to grow so that said silicon grains could be contacted with one another to thereby form continuous silicon grains.

9. The method of producing the semiconductor device according to claim 1, wherein in the processing step, SiH₄ or Si₂H₆ is introduced as the silicon-base gas, and PH₃, B₂H₆, BCl₃ or AsH₃ is introduced as the dopant gas.

10. A method of producing a semiconductor device, comprising the steps of:
carrying a substrate with an insulating film formed on its surface into a processing chamber;
processing the substrate to form silicon grains on the insulating film formed on the surface of the substrate by introducing at least a silicon-base gas into the processing chamber; and
carrying the processed substrate out of the processing chamber,
wherein in the processing step, a silicon-base gas and a dopant gas are introduced into the processing chamber with the temperature and the pressure inside the processing chamber being so controlled that, when the silicon-base gas is introduced singly, the silicon-base gas is not thermally decomposed under the controlled condition, and the thermal decomposition of the silicon-base gas is brought about as triggered by the action of the dopant gas.

11. A substrate processing apparatus, comprising:
a processing chamber that processes a substrate with an insulating film formed on its surface;
a silicon-base gas supply system that feeds a silicon-base gas into the processing chamber;
a dopant gas supply system that feeds a dopant gas into the processing chamber;
an exhaust system that exhausts inside the processing chamber;
a heater that heats the substrate in the processing chamber; and
a controller that controls the silicon-base gas supply system, the dopant gas supply system, the exhaust system and the heater in such a manner that the temperature and the pressure inside the processing chamber could be set at a temperature and a pressure at which, when the silicon-base gas is introduced singly, the silicon-base gas is not thermally decomposed, wherein a silicon-base gas and a dopant gas are introduced into the processing chamber having the controlled temperature and pressure so that the flow rate of the dopant gas could be equal to or more than the flow rate of the silicon-base gas, thereby forming silicon grains on the insulating film formed on the surface of the substrate.
